(19) United States
(12) Patent Application Publication
(10) Pub. No.: US 2026/0074158 A1
(43) Pub. Date: Mar. 12, 2026

(54) VERTICAL PLASMA SOURCE

(71) Applicant: Applied Materials, Inc., Santa Clara, CA (US)

(72) Inventors: ANANTHA SUBRAMANI, San Jose, CA (US); KALLOL BERA, San Jose, CA (US); SEYYED FAZELI, Santa Clara, CA (US); RUPALI SAHU, Milpitas, CA (US)

(21) Appl. No.: 18/827,437

(22) Filed: Sep. 6, 2024

(51) Int. Cl. H01J 37/32

(52) U.S. Cl. CPC H01J 37/32541; H01J 37/32091; H01J 37/32559; H01J 37/32954

(57) ABSTRACT

Embodiments disclosed herein include a plasma source including a ground electrode including a plurality of ground electrode portions. The plasma source also includes a power electrode including a plurality of power electrode portions. Ones of the power electrode portions are interleaved with ones of the ground electrode portions.

### FIELD

Embodiments of the present disclosure pertain to the field of semiconductor processing and, in particular, vertical plasma sources.

### DESCRIPTION OF RELATED ART

Semiconductor device formation is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

Some ALD systems, especially spatial ALD systems with rotating substrate platens, benefit from a modular plasma source, such as a source that can be easily inserted into the system. The plasma source consists of a volume where plasma is generated, and a way to expose a workpiece to a flux of charged particles and active chemical radical species.

### SUMMARY

Embodiments disclosed herein include a plasma source including a ground electrode including a plurality of ground electrode portions. The plasma source also includes a power electrode including a plurality of power electrode portions. Ones of the power electrode portions are interleaved with ones of the ground electrode portions.

Embodiments disclosed herein include a process chamber including a pedestal for supporting a workpiece in a processing volume. A plasma source is in a portion of the processing volume above the pedestal. The plasma source includes a ground electrode including a plurality of ground electrode portions, and a power electrode including a plurality of power electrode portions, where ones of the power electrode portions are interleaved with ones of the ground electrode portions. A chamber top or lid is over the plasma source.

Embodiments disclosed herein include a method of generating a plasma. The method includes powering a plasma source, the plasma source including a ground electrode having a plurality of ground electrode portions, and a power electrode having a plurality of power electrode portions, where ones of the power electrode portions are interleaved with ones of the ground electrode portions.

### BRIEF DESCRIPTION OF THE DRAWINGS

FIG. 1 shows an isometric view of a portion of a processing chamber.

FIG. 2 illustrates an angled cross-sectional view of a circular vertical plasma source, and an exploded portion, in accordance with an embodiment of the present disclosure.

FIG. 3A illustrates a cross-sectional view of a circular vertical plasma source, in accordance with an embodiment of the present disclosure.

FIG. 3B illustrates a cross-sectional view of a circular vertical plasma source, in accordance with an embodiment of the present disclosure.

FIG. 3C illustrates a cross-sectional view of a circular vertical plasma source, in accordance with an embodiment of the present disclosure.

FIG. 4 is a plot representing electron density as a function of radius for an exemplary circular vertical plasma source including cladded electrodes, in accordance with an embodiment of the present disclosure.

FIG. 5 is a plot representing electron density as a function of radius for an exemplary circular vertical plasma source including relatively thick bare electrodes, in accordance with an embodiment of the present disclosure.

FIG. 6 is a plot representing electron density as a function of radius for an exemplary circular vertical plasma source including relatively thin bare electrodes, in accordance with an embodiment of the present disclosure.

FIG. 7 is a plot representing ion flux as a function of radius for an exemplary circular vertical plasma source including cladded electrodes, in accordance with an embodiment of the present disclosure.

FIG. 8 is a plot representing ion flux as a function of radius for an exemplary circular vertical plasma source including relatively thick bare electrodes, in accordance with an embodiment of the present disclosure.

FIG. 9 is a plot representing ion flux as a function of radius for an exemplary circular vertical plasma source including relatively thin bare electrodes, in accordance with an embodiment of the present disclosure.

FIG. 10 is a schematic representation of a plasma processing system, in accordance with an embodiment of the present disclosure.

FIG. 11A is a diagram illustrating a top view of the plasma treatment chamber having a multiphase rotating crossflow operation according to one embodiment.

FIGS. 11B and 11C illustrate cross-section views of the plasma treatment chamber in different embodiments.

FIG. 12 illustrates a diagrammatic representation of a machine in the exemplary form of a computer system within which a set of instructions, for causing the machine to perform any one or more of the methodologies described herein, may be executed according to an embodiment.

### DETAILED DESCRIPTION

The disclosed embodiments relate to vertical plasma sources. In the following description, numerous specific details are set forth, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

In accordance with one or more embodiments of the present disclosure, methods and apparatuses for exciting a uniform plasma with suitable characteristics for materials processing, e.g., etching, deposition or surface modification, for a substrate are described. Embodiments can employ a circular vertical plasma source. In one embodiment, a plasma source has a powered electrode and ground return at the top. Such an architecture can be implemented to decouple plasma grounding and can enable applications where pedestal grounding has been a challenge.

Thermal ALD and CVD processes frequently incorporate treatments for film quality enhancements. These treatments typically include energetic or reactive species. Plasma sources are a primary source for such species. Some concerns of plasma sources include energetic bombardment through ions and contamination of materials from the plasma source due to sputtering. To provide context, state-of-the-art approaches have implemented pedestal grounding. Pedestal grounding has been a challenge. There are currently no alternatives for a plasma source with powered electrode and ground return at the top.

Embodiments can be implemented to provide plasma excitation for large area substrate processing that overcomes practical problems: (1) RF dielectric window size limitations in suitable material for plasma processing, (2) plasma non-uniformities with large area substrates due to distributed circuit (standing wave) effects, voltage and current spatial variation along source, (3) minimizing capacitive coupling on unwanted surfaces (inductively coupled plasma (ICP) windows and ground electrodes), (3) maximizing capacitive coupling at substrate. Advantages for implementing embodiments described herein can include overcoming the above issues.

In accordance with one or more embodiments of the present disclosure, RF hot and RF ground electrodes are in the form of rings and are spaced apart. Gas can be flowed in between the two electrodes. Embodiments can include a vertical plasma source and/or decoupled plasma grounding. Embodiments can include a circular plasma source.

In one embodiment, a circular voltage plasma source (Circular VPS) is described. In one embodiment, a plasma source with powered electrode and ground return at the top is described. In one embodiment, decouples plasma grounding is described.

Implementation of embodiments described herein can include the formation of silicon nitride (SiN), e.g., for microwave high quality films. Implementation of embodiments described herein can include the formation of low or mid quality oxide. Implementation of embodiments described herein can include molybdenum reduction or preclean, e.g., for plasma enhanced atomic layer deposition (PEALD). Implementation of embodiments described herein can include spatial mode applications. Implementation of embodiments described herein can include inductively coupled plasma (IDCCP) H2 plasma recombination at ground plate with the retention of an active species.

Embodiments can include circular voltage plasma sources with metal electrodes having quartz cladding thereon. Embodiments can include circular voltage plasma sources with relatively thick bare metal electrodes. Embodiments can include circular voltage plasma sources with relatively thin bare metal electrodes.

In case of substrates or substrate holders that are rotated during processing, for linear radial plasma sources in any system with a rotating susceptor (also called a platen), the plasma exposure (treatment) is larger at the wafer inner diameter compared to the outer diameter by a factor of about 2.7. Therefore, for uniform plasma exposure, the plasma should be stronger at the outer diameter than the inner diameter. Therefore, there is a need in the art for plasma sources that achieve uniform plasma exposure in rotating platen processing systems.

Plasma source assemblies including an RF hot electrode having a body and at least one return electrode spaced from the RF hot electrode to provide a gap in which a plasma can be formed. An RF feed is connected to the RF hot electrode at a distance from the inner peripheral end of the RF hot electrode that is less than or equal to about 25% of the length of the RF hot electrode. The RF hot electrode can include a leg and optional triangular portion near the leg that extends at an angle to the body of the RF hot electrode. A cladding material on one or more of the RF hot electrode and the return electrode can be variably spaced or have variable properties along the length of the plasma gap

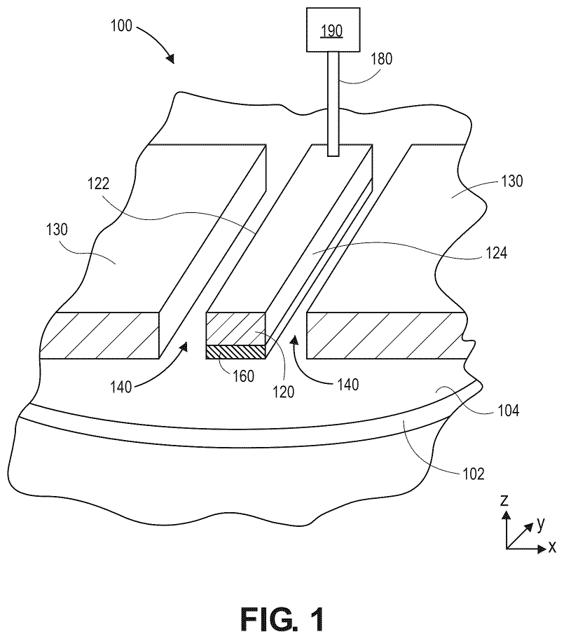

FIG. 1 shows an isometric view of a portion of a processing chamber.

Referring to FIG. 1, a plasma source assembly 100 has at least one RF hot electrode 120 with a first surface 122 oriented substantially parallel to the flow path. A susceptor assembly 102 has a top surface to support and rotate a plurality of substrates 104 around a central axis beneath the flow path. At least one return electrode 130 is within a housing and has a first surface 124 oriented parallel to the flow path and spaced from the first surface 122 of the RF hot electrode 120 to form a gap 140. The RF hot electrode 120 can have a RF hot electrode cladding 160 positioned so that the RF hot electrode 120 is not exposed directly to a substrate 104 or susceptor assembly 102. An RF feed 180 connects a power source 190 to the RF hot electrode 120. The RF feed 180 can be a coaxial RF feed line.

In another aspect, substrates may not rotated during processing. By contrast to the linear electrode of the vertical plasma source of FIG. 1, embodiments described herein are directed to circular vertical plasma sources. In one such embodiment, a circular vertical plasma source is used to process a substrate that is not rotated during processing. In an alternative such embodiment, a circular vertical plasma source is used to process a substrate that is rotated during processing.

Embodiments described herein can be implemented to overcome state-of-the-art problems with plasma sources to reduce voltage and current variation. In an embodiment, a substrate support pedestal resides in a vacuum chamber with a top surface generally facing and generally parallel to a vacuum chamber inside top ceiling surface. The chamber walls are typically grounded and may be bare metal (typically aluminum), anodized, coated, or employ wall liners. The pedestal typically includes an electrostatic chuck (‘esc’), monopolar or multipolar, for clamping a substrate (semiconductor, dielectric or conductor) to a surface to facilitate heat transfer (temperature control) and can optionally power coupling (biasing), and to maintain flatness and parallelism of a substrate to said surface. A heat transfer fluid may be exchanged between pedestal or electrostatic chuck (ESC) and an external heat exchanger or chiller. A heat transfer gas may be supplied to the interface between esc surface and backside of substrate to facilitate heat transfer there between. The pedestal or ESC may include electrical resistance heaters within its structure, with filtering isolation. An RF bias generator can optionally be connected via a matching network and optional transmission line to pedestal or ESC. An electrostatic chuck voltage source may be connected to the ESC to establish and maintain an electrostatic clamping force (pressure) between substrate and ESC. RF bias and electrostatic chucking voltage may be connected to common electrode with the ESC, or may be connected to separate electrodes within the ESC. Alternatively, ESC chucking voltage may be connected to a chucking electrode within the ESC, and RF bias may be connected to pedestal conductive electrode. In any of all of these cases, filters may be employed to properly isolate said power or voltage or current source from one another, and to isolate heater elements from external ac or dc power supply. In one embodiment, the pedestal is at a fixed position relative to chamber. In another embodiment, the pedestal has z-axis motion to facilitate substrate transfer to/from transfer chamber and robot blade. In another embodiment, the pedestal has an adjustable height, providing a process-recipe or process-operation selectable gap between substrate pedestal and rod/tube array to maximize process uniformity. In yet another embodiment, the pedestal may rotate or oscillate in x-y plane to maximize process uniformity.

In accordance with an embodiment of the present disclosure, an upper region of a process chamber includes a circular vertical plasma source. In an embodiment, the (conductive) pedestal and ESC may extend beyond the size of the substrate to maximize uniformity of sheath (boundary layer in plasma) electric field over the substrate. The pedestal and ESC may be surrounded along the edge(s) with dielectric, and a grounded metal (uncoated or coated) may surround the dielectric. A process kit, dielectric or semiconductor, may cover the exposed portion of the ESC outside the substrate, and may extend over the surrounding dielectric region.

In an embodiment, gas can be introduced through one or more inlets or nozzles in the chamber ceiling and/or through the circular vertical plasma source, and may evacuated with a pump (or turbomolecular pump) in a central region below the pedestal or other asymmetric region in the chamber bottom or one or more sides. With a non-central/symmetric pump port location, it may be advantageous to use a gas manifold or flow baffle to facilitate uniform pumping and pressure distribution. Multiple pump ports/pumps may be employed at, for example, 4 bottom corners, for a 4-fold symmetric pumping arrangement. A throttle valve and gate valve, or a throttling gate valve would typically be employed in conjunction with a pressure gauge (e.g., capacitance manometer) for chamber pressure control.

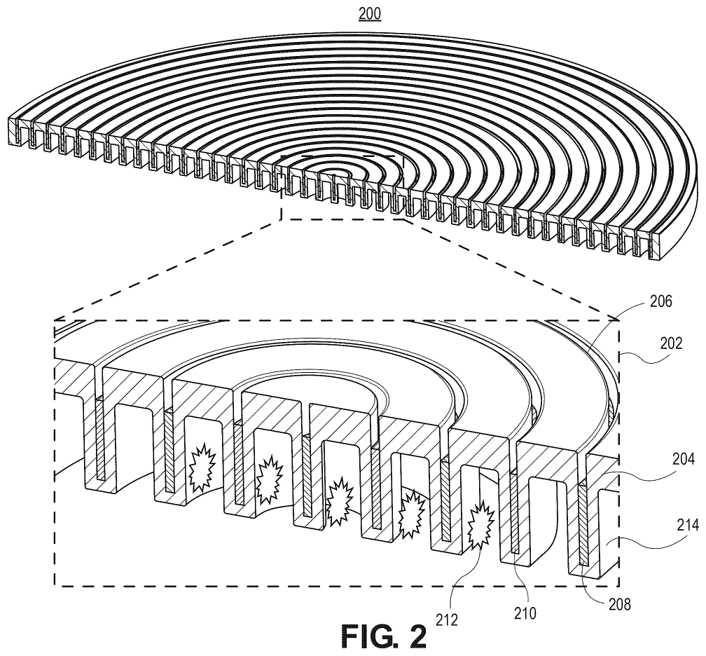

As an exemplary structure, FIG. 2 illustrates an angled cross-sectional view of a circular vertical plasma source 200, and an exploded portion 202, in accordance with an embodiment of the present disclosure.

Referring to FIG. 2, the circular vertical plasma source 200 includes a housing 204 of concentric circular sensor trenches 206. The trenches include alternating RF Hot electrodes 208 and RF ground (GND) electrodes 210. A plasma 212 can be struck between the alternating RF Hot electrodes 208 and RF ground (GND) electrodes 210.

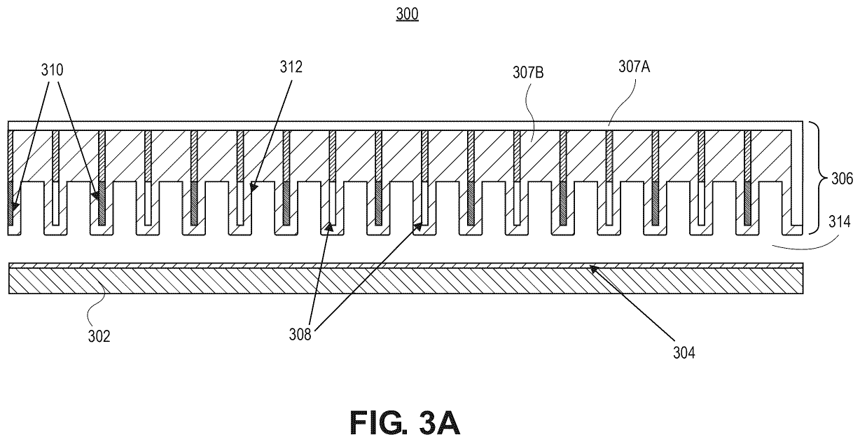

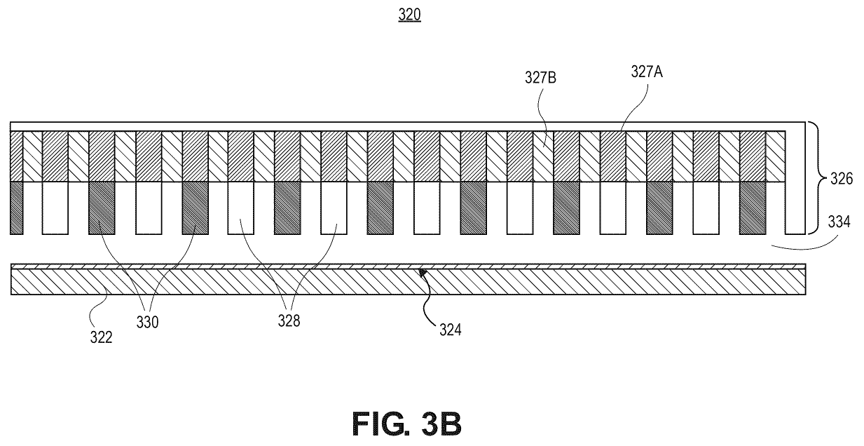

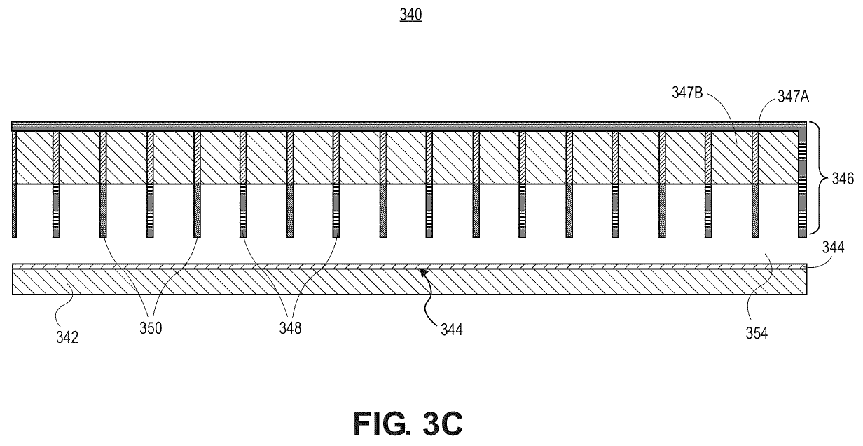

As an exemplary structure including cladded electrodes, FIG. 3A illustrates a cross-sectional view of a circular vertical plasma source, in accordance with an embodiment of the present disclosure.

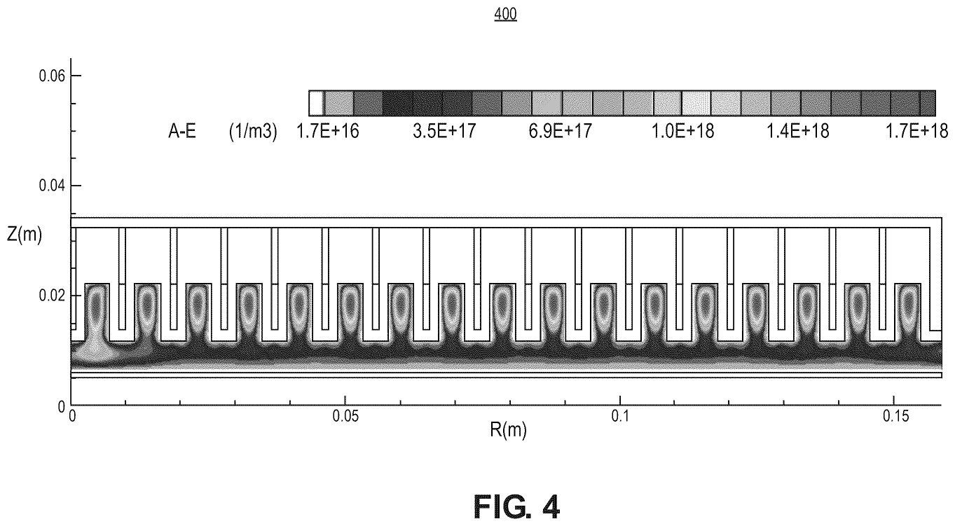

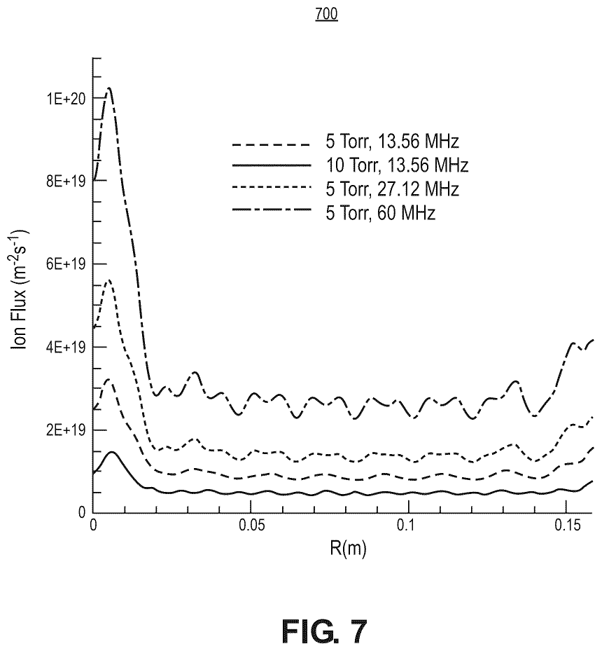

Referring to FIG. 3A, a circular vertical plasma source 300 is above a substrate holder 302 supporting a substrate 304 by a gap 314. The circular vertical plasma source 300 includes a housing 306, e.g., having a base 307A and a holder 307B. Powered electrodes 310 are alternating with ground electrodes 308. A cladding layer 312, such as a quartz cladding layer, covers exposed portions of the powered electrodes 310 and the ground electrodes 308. FIG. 4 is a plot 400 representing electron density as a function of radius for an exemplary circular vertical plasma source including cladded electrodes, in accordance with an embodiment of the present disclosure. FIG. 7 is a plot 700 representing ion flux as a function of radius for an exemplary circular vertical plasma source including cladded electrodes, in accordance with an embodiment of the present disclosure.

As an exemplary structure including bare electrodes, FIG. 3B illustrates a cross-sectional view of a circular vertical plasma source, in accordance with an embodiment of the present disclosure.

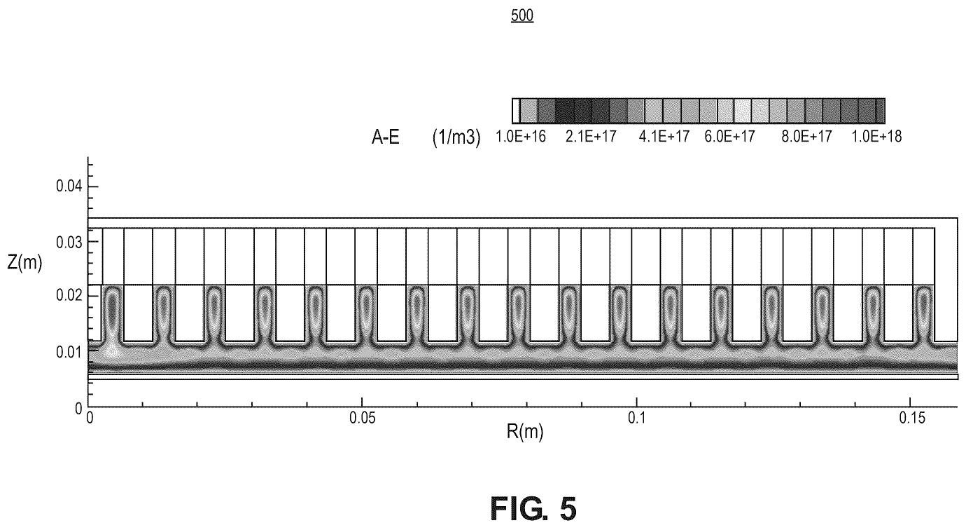

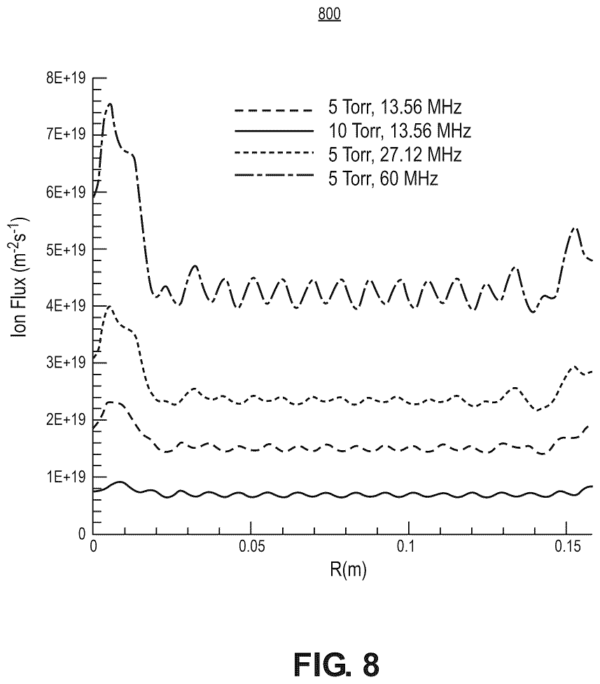

Referring to FIG. 3B, a circular vertical plasma source 320 is above a substrate holder 322 supporting a substrate 324 by a gap 334. The circular vertical plasma source 320 includes a housing 326, e.g., having a base 327A and a holder 327B. Powered electrodes 330 are alternating with ground electrodes 328. The powered electrodes 310 and the ground electrodes 308 are bare electrodes, e.g., having a relatively thick lateral width. FIG. 5 is a plot 500 representing electron density as a function of radius for an exemplary circular vertical plasma source including relatively thick bare electrodes, in accordance with an embodiment of the present disclosure. FIG. 8 is a plot 800 representing ion flux as a function of radius for an exemplary circular vertical plasma source including relatively thick bare electrodes, in accordance with an embodiment of the present disclosure.

As another exemplary structure including bare electrodes, FIG. 3C illustrates a cross-sectional view of a circular vertical plasma source, in accordance with an embodiment of the present disclosure.

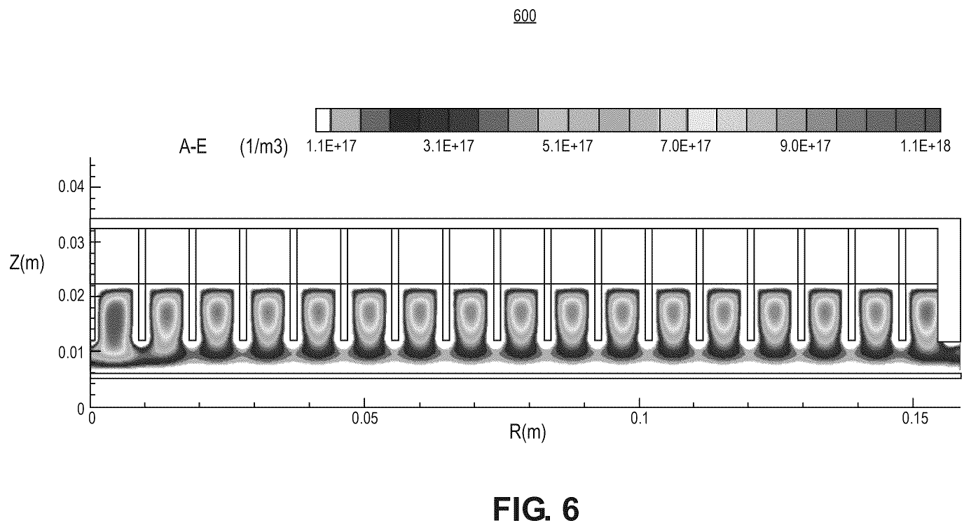

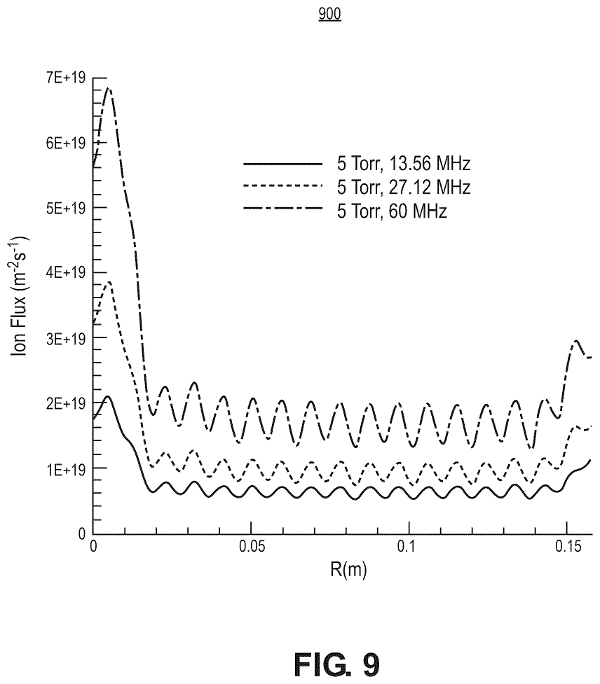

Referring to FIG. 3C, a circular vertical plasma source 340 is above a substrate holder 342 supporting a substrate 344 by a gap 354. The circular vertical plasma source 340 includes a housing 346, e.g., having a base 347A and a holder 347B. Powered electrodes 350 are alternating with ground electrodes 348. The powered electrodes 350 and the ground electrodes 348 are bare electrodes, e.g., having a relatively thick lateral width. FIG. 6 is a plot 600 representing electron density as a function of radius for an exemplary circular vertical plasma source including relatively thin bare electrodes, in accordance with an embodiment of the present disclosure. FIG. 9 is a plot 900 representing ion flux as a function of radius for an exemplary circular vertical plasma source including relatively thin bare electrodes, in accordance with an embodiment of the present disclosure.

With reference again to FIGS. 2, 3, 4 and 5, in accordance with embodiments of the present disclosure, a plasma source includes a ground electrode including a plurality of ground electrode portions. The plasma source also includes a power electrode including a plurality of power electrode portions. Ones of the power electrode portions are interleaved (e.g., an alternating pattern) with ones of the ground electrode portions.

In one embodiment, a pedestal beneath the circular vertical plasma source is not coupled to ground and is not coupled to RF. In an alternative embodiment, a pedestal beneath the circular vertical plasma source is coupled to ground or to RF, or to both ground and RF.

In one embodiment, the plurality of ground electrode portions and the plurality of power electrode portions are bare electrode portions. In one embodiment, the plurality of ground electrode portions and the plurality of power electrode portions are cladded electrode portions. In one embodiment, the plurality of ground electrode portions includes a plurality of concentric circular-shaped portions. In one embodiment, the plurality of power electrode portions includes a plurality of concentric circular-shaped portions. In one embodiment, the plurality of ground electrode portions includes a first plurality of concentric circular-shaped portions, and the plurality of power electrode portions includes a plurality of concentric circular-shaped portions. In one embodiment, the plurality of ground electrode portions are electrically coupled together, and the plurality of power electrode portions are electrically coupled together. In one embodiment, the plasma source is for operating at a temperature in the range of 400-500 degrees Celsius.

In an embodiment, a workpiece or substrate for processing may include any substrate that is commonly used in semiconductor manufacturing environments. For example, the workpiece may include a semiconductor wafer. In an embodiment, semiconductor materials may include, but are not limited to, silicon or III-V semiconductor materials. The semiconductor wafer may be a semiconductor-on-insulator (SOI) substrate in some embodiments. Typically, semiconductor wafers have standard dimensions, (e.g., 200 mm, 300 mm, 450 mm, or even larger, and may be circular, square or rectangular). However it is to be appreciated that the workpiece may have any dimension. Embodiments may also include workpieces that include non-semiconductor materials, such as glass or ceramic materials. In an embodiment, the workpiece may include circuitry or other structures manufactured using semiconductor processing equipment. In yet another embodiment, the workpiece may include a reticle or other lithography mask object.

In another aspect, plasma processing systems are described.

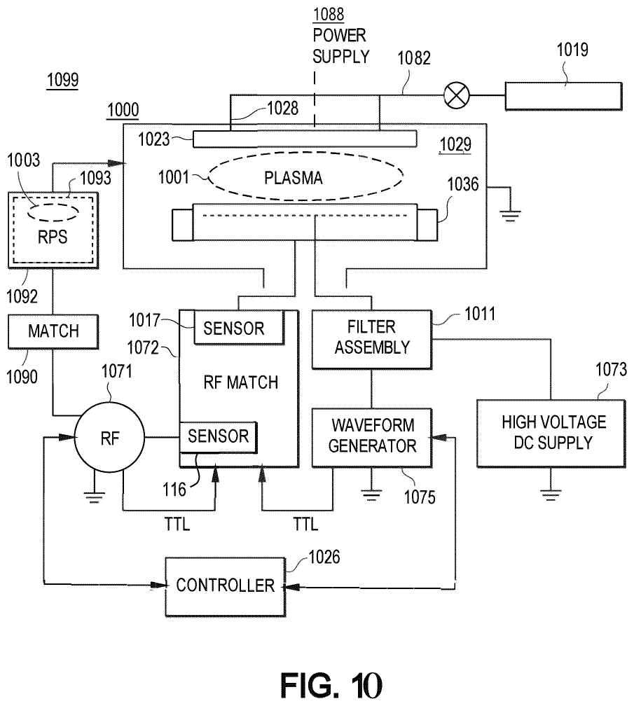

FIG. 10 is a schematic representation of a plasma processing system, in accordance with one or more embodiments of the present disclosure. FIG. 10 is provided to show a conventional plasma arrangement that can be modified to include a circular vertical plasma source. In an embodiment, a circular vertical plasma source is included within or adjacent to the chamber lid 1023. In one embodiment, a power source 1088 is add to power the circular vertical plasma source. The RPS 192 can be optionally included or removed. The RF 171 can be optionally included or removed. The high voltage DC supply 173 can be optionally included or removed.

The plasma processing system 1099 is configured for plasma-assisted etching processes, such as a reactive ion etch (RIE) plasma processing. The plasma processing system 1099 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma chamber clean processing, plasma-enhanced atomic layer deposition (PEALD) processes, plasma treatment processing, plasma-based ion implant processing, or plasma doping (PLAD) processing. In one configuration, as shown in FIG. 1A, the plasma processing system 1099 is configured to form a capacitive coupled plasma (CPP). However, in some embodiments, a plasma may alternately be generated by an inductively coupled source disposed over a processing region of the plasma processing system 1099.

The plasma processing system 1099 includes a processing chamber 1000, a substrate support assembly 1036, a gas delivery system 1082, a high DC voltage supply 1073, a radio frequency (RF) generator 1071, and an RF match 1072 (e.g., RF impedance matching network). A chamber lid 1023 includes one or more sidewalls and a chamber base that are configured to withstand the pressures and energy applied to them while a plasma 1001 is generated within a vacuum environment maintained in a processing volume 1029 of the processing chamber 1000 during processing.

The gas delivery system 1082, which is coupled to the processing volume 1029 of the processing chamber 1000 is configured to deliver at least one processing gas from at least one gas processing source 1019 to the processing volume 1029 of the processing chamber 1000. The gas delivery system 1082 includes the processing gas source 1019 and one or more gas inlets 1028 positioned through the chamber lid 1023. The gas inlets 1028 are configured to deliver one or more processing gasses to the processing volume 1029 of the processing chamber 1000. The processing gas source 1019 is also coupled to an inlet port of the remote plasma source (RPS) 1092 so that a process gas can be provided through the RPS 1092 to transform the gas into a reactive plasma and then to the processing region of the process chamber 1000.

The processing chamber 1000 includes an upper electrode (e.g., the chamber lid 1023) and a lower electrode (e.g., the substrate support assembly 1036) positioned in the processing volume 1029 of the processing chamber 1000. The upper and lower electrodes face one another. In one embodiment, the RF generator 1071 is electrically coupled to the lower electrode. The RF generator 1071 is configured to deliver an RF signal to ignite and maintain the plasma 1001 between the upper and lower electrodes. In some alternative configurations, the RF generator 1071 can also be electrically coupled to the upper electrode. For example, the RF generator 1071 may deliver an RF source power to an RF baseplate within a cathode assembly (e.g., in the substrate support assembly 1036) for plasma production, whereas the upper electrode is grounded. A center frequency of the RF source power can be from 13.56 MHz to very high frequency band such as 40 MHz, 60 MHz, 120 MHz or 162 MHz. In some examples, the RF source power can also be delivered through the upper electrode. The RF source power can be operated in a continuous mode or a pulsed mode. A pulsing frequency of the RF power can be from 100 to 10kHz, and duty cycles are ranging from 5% to 95%. The RF generator 1071 has a frequency tuning capability and can adjust its RF power frequency within e.g., ±5% or ±10%. In some embodiments, the RF generator 1071 switches the RF power frequency at a predefined speed (e.g., two nanoseconds, fifty nanoseconds, etc.).

The substrate support assembly 1036 may be coupled to a high voltage DC supply 1073 that supplies a chucking voltage thereto. The high voltage DC supply 1073 may be coupled to a filter assembly 1078 that is disposed between the high DC voltage supply 1073 and the substrate support assembly 1036.

The filter assembly 1078 is configured to electronically isolate the high voltage DC supply 1073 during plasma processing. In one configuration, a static DC voltage is between about −5000V and about 5000V, and is delivered using an electrical conductor (such as a coaxial power delivery line). The filter assembly 1078 may include multiple filtering components or a single common filter.

The substrate support assembly 1036 is coupled to a pulsed voltage (PV) waveform generator 1075 configured to supply a PV to bias the substrate support assembly 1036 through a filter assembly 1011. The PV waveform generator 1075 is coupled to the filter assembly 1078. The filter assembly 1078 is disposed between the PV waveform generator 1075 and the substrate support assembly 1036. The filter assembly 1078 is configured to electronically isolate the PV waveform generator 1075 during plasma processing.

The substrate support assembly 1036 is coupled to the RF generator 1071 configured to deliver an RF signal to the processing volume 1029 of the processing chamber 1000. The RF generator 1071 is electronically coupled to the RF match 1072 disposed between the RF generator 1071 and the processing volume 1029 of the processing chamber 1000. For example, the RF match 1072 is an electrical circuit used between the RF generator 1071 and a plasma reactor (e.g., the processing volume 1029 of the processing chamber 1000) to optimize power delivery efficiency. One or more RF filters (e.g., within the RF match 1072) are designed to only allow powers in a selected frequency range, and to isolate RF power supplies from each other. In some cases, a bandwidth of an RF filter has to be larger than a frequency tuning range of the RF generator 1071.

During the plasma processing, the RF generator 1071 delivers an RF signal to the substrate support assembly 1036 via the RF match 1072. For example, the RF signal is applied to a load (e.g., gas) in the processing volume 1029 of the processing chamber 1000. If an impedance of the load is not properly matched to an impedance of a source (e.g., the RF generator 1071), a portion of a waveform can reflect back in an opposite direction. Accordingly, to prevent a substantial portion of the waveform from reflecting back, some implementations find a match impedance (e.g., a matching point) by adjusting one or more components of the RF match 1072 as the source and load impedances change.

The RF match 1072 is electrically coupled to the RF generator 1071, the substrate support assembly 1036, and the PV waveform generator 1075. The RF match 1072 is configured to receive a synchronization signal from either or both of the RF generator 1071 and the PV waveform generator 1075.

The RF generator 1071 and the PV waveform generator 1075 are each directly coupled to a system controller 1026. The system controller 1026 synchronizes the respective generated RF signal and PV waveform.

Voltage and current sensors can be placed at an input and/or output of the RF match 1072 to measure impedance and other parameters. These sensors can be synchronized using an external transistor-transistor logic (TTL) synchronization signal from an advanced waveform generator and/or RF generators or using measured voltage and current data to determine timing internally. For example, an output sensor 1017 is configured to measure the impedance of the plasma processing chamber 1000, and other characteristics such as the voltage, current, harmonics, phase, and/or the like. An input sensor 1016 is configured to measure the impedance of the RF generator 1071 and other characteristics such as the voltage, current, harmonics, phase, and/or the like. Based on either of the synchronization signals or the characteristics of the plasma processing chamber 1000, the RF match 1072 is able to capture fast impedance changes and optimize impedance matching.

The PV waveform generator 1075 is used to supply a PV waveform and/or a tailored voltage waveform, which is a sum of harmonic frequencies associated with the waveform. The PV waveform generator 1075 may output a synchronization TTL signal to the RF match 1072. The voltage waveform is coupled to a bias electrode through the filter assembly 1078. The high DC voltage supply 1073 is applied to chuck a substrate during a process for a thermal control. In some cases, there can be a third electrode at an edge of the cathode assembly for edge uniformity control.

As shown, the plasma processing system may include a remote plasma source (RPS) 1092, which may be used to clean the chamber after one or more deposition processes. In some aspects, the RPS 1092 may be driven by the same RF generator 1071 used for substrate processing, although a separate generator may be used. A match 1090 may be coupled between the generator 1071 and the RPS 1092 to reduce reflections and increase power efficiency. The match 1090 may be a fixed match, in some cases, although a variable match may be used in some applications. In some aspects, frequency tuning may be used to perform matching. In some aspects, an arrangement may be used where power from generator 1071 is split so both RPS plasma 1003 and in-chamber plasma 1001 are enabled with part of the power going to the RPS 1092 and part going to the processing chamber.

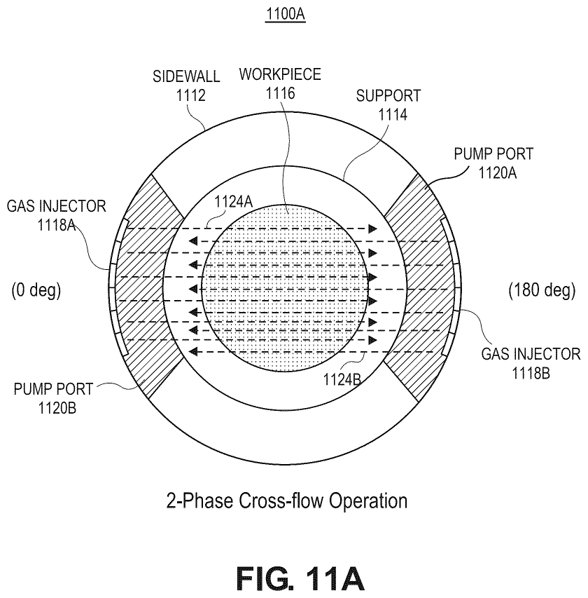

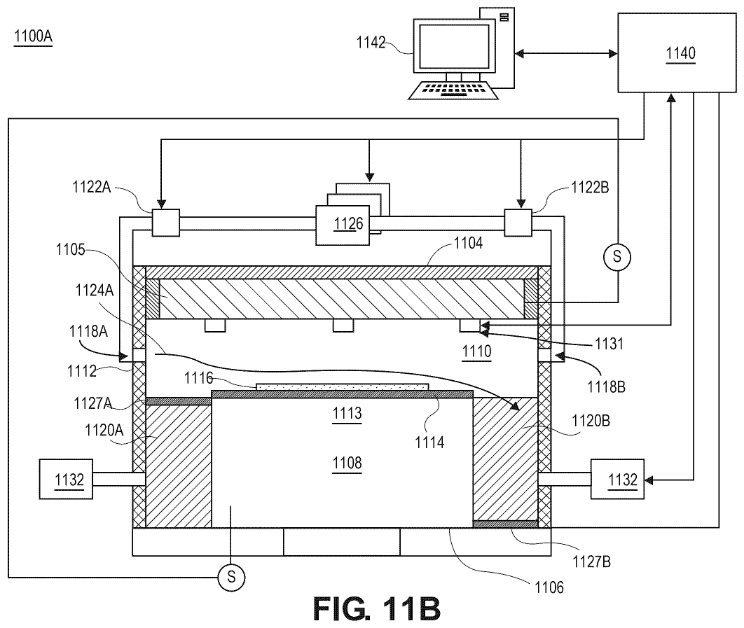

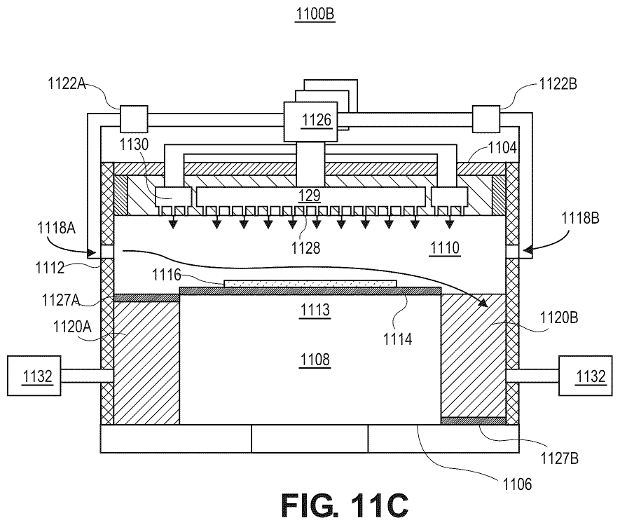

In another aspect, a plasma chamber with rotating modulated cross-flow. Such rotating modulated cross-flow can be used in combination with the above described circular vertical plasma sources. In particular, an alternative embodiment utilizes ‘cross-flow’, with gas inlets located generally near one wall or side region of chamber (on wall, ceiling, or bottom) and pumping generally located on/near opposite side/wall/bottom of chamber, examples of which are described below in association with FIGS. 11A-11C. This arrangement facilitates higher horizontal gas velocity and lower gas residence time across the substrate, which can be suitable for some processes. A second inlet and opposite outlet can be located 180 degrees rotated with respect to the first set or each, and sequential or phase 2-phase operation can alternate flow direction. Finally, inlets and outlets can be placed on/near each side, with inlets 90 degrees apart, and respective outlets opposite said inlets, and 4-phase operation can operate sequentially or with phased operation to rotate flow for best uniformity. Alternatively, a single inlet on 1 side and outlet on opposite side can be combined with a rotating substrate pedestal for best uniformity.

To provide context, traditional plasma chambers (i.e., CCP or ICP) typically inject gas axisymmetrically over a workpiece from gas inlet holes that are typically located directly above the workpiece or symmetrically around its periphery. Axisymmetric gas flow can result in pressure and concentration gradients and the gas hole inlets may breakdown, creating non-uniformities in the workpiece. That is, as wear occurs in gas holes in the dense, high |E| plasma regions, geometry of the holes change and as plasma penetrates, the holes may modify the local plasma characteristics in the vicinity of the holes. In addition, the local gas flow rate and velocity may change as a result of geometric changes. Therefore, the showerheads need to be replaced relatively often, increasing cost of the workpiece.

Accordingly, embodiments disclosed herein are directed to a plasma chamber (e.g., CCP or ICP) with a multiphase rotating modulated gas cross-flow for etching, deposition or other materials treatment. The plasma treatment chamber includes two or more gas injectors and two or more pump ports along a sidewall. In a first phase, one of the gas injectors forces a gas flow in one direction generally parallel and across a surface of a workpiece or device, where the gas is then pumped out via a pump port. In a second phase, gas flow is rotated by using another gas injector to force the gas flow in a different direction generally parallel and across the surface of the workpiece, where the gas is then pumped out via another pump port. In another embodiment, gas inlet valves coupled to the gas injector and/or throttle valves coupled to the pump ports can be used to modulate the rotating gas flows.

The plasma treatment chamber with rotating modulated gas cross-flow eliminates the need for showerheads (and gas inlet holes) in the dense, high |E| plasma regions, and therefore prevents the source of plasma non-uniformity. The disclosed embodiments prevent plasma from forming in gas holes due to proximity to dense plasma or breakdown due to high electric fields, leading to non-uniformity and plasma characteristics changing over time change. The disclosed embodiments avoid high center-to-edge pressure and concentration gradients that cause center-to-edge processing differences. Pressure distribution can be tailored across the plasma volume to minimize plasma non-uniformity. In addition, the disclosed embodiments eliminate stagnant low-gas velocity regions (i.e., center of the workpiece) for uniform reactant and byproduct removal.

FIGS. 11A-11C are diagrams illustrating embodiments of a plasma treatment chamber of a plasma reactor having a multiphase rotating crossflow operation. FIG. 11A is a diagram illustrating a top view of the plasma treatment chamber having a multiphase rotating crossflow operation according to one embodiment. FIGS. 11B and 11C illustrate cross-section views of the plasma treatment chamber in different embodiments. In accordance with one or more embodiments of the present disclosure, a circular vertical plasma source, such as described above, can be incorporated into the chambers described below.

Referring to both FIGS. 11A and 11B, the plasma treatment chamber 1100A includes one or more chamber sidewalls 1112 with a support surface 1114 therein to hold a workpiece 1116 (e.g., a semiconductor wafer; which can be a large substrate and/or a square substrate) for treatment. The plasma treatment chamber 1100 may be used to perform a variety of treatments to the workpiece 1116, such as etching, deposition, surface treatment or material modification, by distributing gases inside the chamber. For example, plasma treatment chamber 1100A may include, but is not limited to, a plasma etch chamber, a plasma enhanced chemical vapor deposition chamber, a physical vapor deposition chamber, an ion implantation chamber, an atomic layer deposition (ALD) chamber, an atomic layer etch (ALE) chamber, or other suitable vacuum processing chamber to fabricate various devices.

In one embodiment shown, the one or more sidewalls 1112 surround a processing region 1110 in which the workpiece 1116 (e.g., wafer or substrate) is treated. In the example shown, the plasma treatment chamber 1100A is shown with an axially symmetrical shape (e.g., a cylindrical) resulting in a single cylindrical sidewall 1112. However, in other embodiments, the plasma treatment chamber 100A may have any other shape, such as an oval, which also results in a single sidewall 1112, or as a square or rectangle, in which case the plasma treatment chamber 1100A would have four sidewalls.

According to the disclosed embodiments, the plasma treatment chamber 1100 includes at least two gas injectors 1118A and 1118B (collectively referred to as gas injectors 1118) and at least two pump ports 1120A and 1120B (collectively referred to as pump ports 1120) located generally along the sidewall(s) 1112. In one embodiment, the gas injectors are formed in the openings through a liner of the sidewall 1112. The plasma treatment chamber 1100A may be configured to use the gas injectors 1118 and the pump ports 1120 to rotate gas flows 1124 laterally across the workpiece 1116 to provide a multiphase rotating crossflow operation. In one embodiment, the multiphase rotating crossflow operation includes at least a 2-phase cycle, and may include a 3-phase cycle, a 4-phase cycle, and so on, wherein each phase gas is injected from one side of plasma treatment chamber 1100A and pumped out generally from an opposite side. As used herein, the phrase “located generally along the sidewall(s)” is intended to describe that any of the gas injectors 1118 and/or pump ports 1120 may be located in a sidewall or horizontally abutting or adjacent to the sidewall, or located in an outer periphery region of the chamber top or an outer periphery region of the chamber bottom.

Rotation of gas flow laterally across the workpiece 1116 may result in improved control of gas velocity and pressure gradients leading to better process uniformity across a wafer and from wafer-to-wafer.

Referring to FIG. 11B, the plasma treatment chamber 1100A further includes a chamber lid 1104 over the sidewall 1112. A support pedestal 1108 may include a support surface 1114 on which the workpiece 1116 is placed. In embodiments, the support pedestal 1108 and the support surface 1114 are fixed and not rotatable, and the workpiece 1116 affixed thereto is not rotated during processing. In an embodiment, the workpiece 1116 is electrostatically affixed to the support surface 1114. In another embodiment, the support surface 1114 is moveable in the axial direction for plasma gap adjustment or wafer transfer. A processing region 1110 in the plasma treatment chamber 1100A is defined by an area between the chamber lid 1104, the support pedestal 1108 (and support surface 1114), and the sidewall 1112. A chamber floor 1106 is beneath the sidewall 1112, and the chamber floor 1106 is below the processing region 1110. The support pedestal 1108 is below the chamber lid 1104 and above the chamber floor 1106, and is surrounded by the sidewall 1112. In embodiments, the chamber lid 1104 and the support surface 1114 may be separated by distance of approximately 50 mm-400 mm. In an embodiment, the plasma treatment chamber 1100A is a parallel plate capacitively coupled plasma (CCP) process chamber where a first electrode 1105 is above the workpiece 1116. A second electrode is included in a location 1113 in support pedestal 1108 below support surface 1114. In one embodiment, the first electrode 1105 is coupled to an RF source having a frequency in a range of 40-200 MHz with a power in a range of 200-10000 Watts. In one embodiment, the second electrode is coupled to ground. A plasma is generated above the wafer and between the two electrodes. In an embodiment, the workpiece 1116 is electrostatically clamped to the support surface 1114 by one or more clamping electrodes in or below the support surface 1114. In embodiments, the workpiece 1116 is coupled to biasing electrodes (e.g., at a low RF frequency in a range of 0.1 to 20 MHz) for additional plasma control during processing. The generated plasma may be pulsed during processing by pulsing the power to the first electrode 1105, which may be or include an ICP array, such as described in embodiments herein.

In an embodiment, the workpiece 1116 may include any substrate that is commonly used in semiconductor manufacturing environments. For example, the workpiece may include a semiconductor wafer. In an embodiment, semiconductor materials may include, but are not limited to, silicon or III-V semiconductor materials. The semiconductor wafer may be a semiconductor-on-insulator (SOI) substrate in some embodiments. Typically, semiconductor wafers have standard dimensions, (e.g., 200 mm, 300 mm, 450 mm, or even larger, and may be circular, square or rectangular). However it is to be appreciated that the workpiece 1116 may have any dimension. Embodiments may also include workpieces that include non-semiconductor materials, such as glass or ceramic materials. In an embodiment, the workpiece 1116 may include circuitry or other structures manufactured using semiconductor processing equipment. In yet another embodiment, the workpiece 1116 may include a reticle or other lithography mask object.

FIGS. 11A and 11B illustrate an example of 2-phase cycle rotating cross-flow operation. In the first phase, gas injector 1118A injects a first gas flow 1124A in a first direction generally parallel to and across a surface of the workpiece 1116 and has an opposing pump port 1120A along the one or more sidewalls 1112 generally opposite of the gas injector 1118A to pump out the gas flow 1124A. In the second phase, gas injector 1118B injects a second gas flow 1124B in a second direction generally parallel to and across a surface of the workpiece 1116 and has an opposing pump port 1120B along the one or more sidewalls 1112 generally opposite of the gas injector 1118B to pump out the gas flow 1124B. In embodiments, the direction of the second gas flow 1124B is different from the direction of the first gas flow 1124A. In one embodiment, generally parallel means within approximately 0° to 15°, and generally opposite means within approximately 0° to 30°.

Thus, gas injector 1118A and the opposing pump port 1120A form one gas injector-pump port pair, while gas injector 1118B and opposing pump port 1120B form a second gas injector-pump port pair. In one embodiment, each of the gas injectors 1118A and 1118B may include an array of individual gas injectors, as shown in FIG. 11A. In an alternative embodiment, each of the gas injectors 1118A and 1118B includes only a single vent gas injector. In some embodiments, gas injector 1118A includes an array of individual gas injectors, and gas injector 1118B is a single vent gas injector, or vice versa.

As shown in FIG. 11A, along the horizontal plane, which is generally parallel to the orientation of the workpiece 1116, each gas injector-pump port pair (i.e., a gas injector and the opposing pump port) are symmetrically located along the sidewall 1112 of the plasma treatment chamber 1100A. Any number of gas injectors 1118 and pump ports 1120 may be provided. In general one gas injector-pump port pair may be offset from an adjacent injector-pump port pair locations by an angle equal to 360 total degrees divided by the number of injector-pump port pairs to ensure equal distribution of the gases. For example, with two injector-pump port pairs, the injector-pump port pairs are offset from one another by 180° (360°/2). With three injector-pump port pairs, the injector-pump port pairs are offset by 120°, and so on. In some embodiments, as shown, a gas injector span is smaller than a span of the corresponding pump port. In other embodiments, the gas injector span is the same as the span of the corresponding pump port. In other embodiments, the gas injector span is larger than the span of the corresponding pump port. Gas can be injected from gas injector openings of various geometry such as holes, slots, and the like, and different gas injectors can have the same or different geometries and sizes.

While in some embodiments, the number of gas injectors 1118 and pump ports 1120 is equal, in other embodiments, the number of gas injectors 1118 and pump ports 1120 may differ. In some embodiments, a single pump port is associated with a corresponding gas injector, as depicted. In other embodiments, an array of pump ports is associated with a corresponding gas injector.

As shown in FIG. 11B, the gas injectors 1118 are located in openings in the sidewall 1112 in the processing region 1110. For example, the openings may be located within a liner of the sidewall 1112. In an embodiment, the openings in the sidewall 1112 are in a location vertically between the chamber lid 1104 and the substrate support pedestal 1108. In the embodiment shown, the openings in the sidewall 1112 are adjacent to a bottom of the chamber lid 1104.

Along the vertical plane, which is generally parallel to the orientation of the support pedestal 1108, locations of the pump ports 1120 may be vertically offset from locations of the gas injectors 1118 by a distance approximately equal to the distance between a bottom of the chamber lid 1104 and a top of the support pedestal 1108 in one embodiment. In this embodiment, the pump ports 1120 may be located in cavities between the sidewall 1112 and the support pedestal 1108, and above the chamber floor 1106. In another embodiment, the pump ports 1120 may be located in additional openings in the sidewall 1112 anywhere between the chamber lid 1104 and the chamber floor 1106. In another embodiment, gas can be injected from peripheral regions of the chamber top, and/or pumped from peripheral regions of the chamber bottom, and over the workpiece processing region and still flow substantially parallel to the workpiece.

As described above, the plasma treatment chamber 1100A of the disclosed embodiments injects gas generally parallel and across the workpiece 1116. This is in contrast to a typical axisymmetric top-down gas flow injection from a “showerhead” electrode in a CCP source reactor, and in contrast to a radial outward/downward gas injection from a nozzle array near a central axis in an ICP or microwave source reactor. In addition, instead of a pump port or pumping plenum located axisymmetrically around the periphery of the workpiece, in embodiments, gas is preferentially pumped out from a side of a workpiece generally opposite the injection side.

In embodiments, the gas flow 1124 of each cross flow phase can be switched on and off to control gas flow rotation. In another embodiment, instead of switching the gas flow 1124 on and off, a modulating function may be applied to a flow rate of the gas flows 1124 from the gas injectors 1118 and/or to an outlet conductance (or pressure) caused by the pump ports 1120 to either approximate open/closed states or to ramp between states using a modulating function, such as sinusoidal. As shown in FIG. 11B, a flow rate of one or both of the first and second gas flows 1124A and 1124B can be modulated using one or more gas inlet valves 1122A and 1122B (e.g., piezoelectric valves) that are coupled to gas injector 1118A and 1118B, respectively. In embodiments, the gas inlet valves 1122A and 1122B are coupled to one or more gas sources 1126, such that a single type of gas, or a mixture of different types of gases, may be injected into the processing region 1110 during each rotation phase. In one embodiment, a constant total gas flow may be applied by the gas injectors 1118 to smoothly and sequentially inject the gas flows across the different sides of the workpiece 1116 in a complete cycle, which may then be repeated as necessary.

In addition, in some embodiments one or more of the pump ports 1120 may be modulated. For example, pump port conductance (pressure) may be modulated using individual pressure control valves 1127A and 1127B on pump ports 1120A and 1120B. Also shown is that the pump ports 1120A and 1120B are coupled to one or more pumps 1132 to evacuate the gas. In the example shown, pressure control valve 1127A in pump port 1120A is in the closed position, while pressure control valve 1127B is shown in the open position to expel the first gas flow 1124A. The pressure control valves 1127A and 1127B may be operated smoothly between two states of conductance or pressure, which are then cycled through in a like sequence as the gas injectors 1118A and 1118B. In one embodiment, pressure control valves 1127A and 1127B include throttle valves.

The plasma processing system 1099 or the plasma chamber 1100A may inject a variety of types of process gases. Exemplary process gases may include the following: i) dielectric etch gases including one or more of CF4, C2F6, CHF3, C4F8, C4F6, C3F6, CH2F2, C3H2F4, NF3, SF6; ii) deposition gases including one or more of CH4, C2H2, CH3F; iii) additional gases for co-flow for either etch or deposition including one or more of Ar, N2, O2, He, Kr, Xe, COS; iv) semiconductor material etch deposition gases including one or more of SiCl4, SiCH2Cl2; v) hydride-based deposition gases including one or more of BH3, AlH3, GaH3, NH3; vi) oxide material etch deposition gases including one or more of SiCl4, SiCH2Cl2, and O2; and vii) annealing gases including one or more of NH3, N2, Ar.

In some embodiments, the plasma processing system 1099 or the plasma treatment chamber 1100A may further include sensors (e.g., sensors 1131) and systems to monitor process chamber conditions including gas flow, velocity, pressure, temperature and the like, with high sensitivities and real time measurement. Particular embodiments can include capacitive wall sensors, on-chip or off-chip thermal sensors, pressure sensors, and/or integrated sensors (capacitive sensors and thermal sensors) on substrates such as ceramic substrate or glass or silicon or flexible substrates. In some embodiments, the sensors can be distributed throughout the chamber to monitor the chamber conditions at various locations, which then can be correlated to overall process performances such as etch rate, etch non-uniformity, particle generation, process drifting, pressure uniformity, etc. In one embodiment, a plurality or an array of pressure sensors can be distributed throughout the chamber to provide data regarding gas flow (e.g., rotation rates, uniformity, velocity) during processing.

FIG. 11B further shows that the plasma treatment chamber 1100A may be connected to a controller 1140, which in turn may be connected to a user interface 1142. In some embodiments, the controller may be coupled to the gas inlet valves 1122, the pressure control valves 1127, the gas sources 1126, the pump 1132 and the sensors 1131 to control operation of the plasma treatment chamber 1100A. A user may set process parameters and monitor operation of the plasma treatment chamber 1100A through the controller 1140 from the user interface 1142.

The multiphase architecture of the plasma treatment chamber enables many different configuration options. For example, FIG. 11C illustrates a cross-section view of the plasma treatment chamber 1100B in an embodiment that includes a top-down gas flow in addition the one or more pairs of gas injectors 1118 and pump ports 1120 that provide side-to-side gas flows. In this embodiment, chamber lid 1104 may be configured with a showerhead plate 1128 (the controller and UI of FIG. 11B are not shown for simplicity). The shower head plate 1128 may have a central manifold 1129 and one or more outer manifolds 1130 for distributing gases into the processing region 1110 along with gases distributed by the gas injectors 1118A and 1118B. Using the showerhead plate 1128, additional gases may be introduced into the chamber with a vertical velocity component, but injection of gasses from one side by gas injector 1118A and pumping out on other side of workpiece 1116 by pump port 1120B generally results in a horizontal component of gas velocity across much of the workpiece 1116. Likewise, while the pump ports 1120 may be on the sidewall 1112, or on an upper or lower surface of chamber, the pump ports 1120 are generally across from the injection side. Therefore, while there may be a component of velocity of exiting gas in the vertical direction, gas velocity is generally horizontal and parallel to the workpiece 1116 in the region above workpiece 1116.

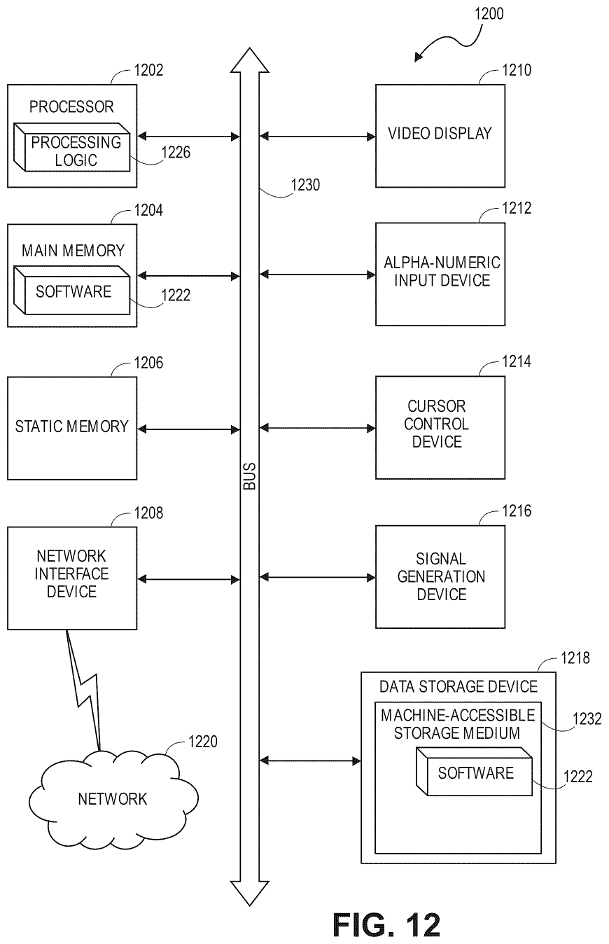

FIG. 12 illustrates a diagrammatic representation of a machine in the exemplary form of a computer system 1200 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein. The computer system may be coupled to, e.g., a circular vertical plasma source, the plasma processing system 1099, or the plasma chamber 1100A, for example.

The exemplary computer system 1200 includes a processor 1202, a main memory 1204 (e.g., read-only memory (ROM), flash memory, dynamic random access memory (DRAM) such as synchronous DRAM (SDRAM) or Rambus DRAM (RDRAM), etc.), a static memory 1206 (e.g., flash memory, static random access memory (SRAM), MRAM, etc.), and a secondary memory 1218 (e.g., a data storage device), which communicate with each other via a bus 1230.

Processor 1202 represents one or more general-purpose processing devices such as a microprocessor, central processing unit, or the like. More particularly, the processor 1202 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1202 may also be one or more special-purpose processing devices such as an application specific integrated circuit (ASIC), a field programmable gate array (FPGA), a digital signal processor (DSP), network processor, or the like. Processor 1202 is configured to execute the processing logic 1226 for performing the operations described herein.

The computer system 1200 may further include a network interface device 1208. The computer system 1200 also may include a video display unit 1210 (e.g., a liquid crystal display (LCD), a light emitting diode display (LED), or a cathode ray tube (CRT)), an alphanumeric input device 1212 (e.g., a keyboard), a cursor control device 1214 (e.g., a mouse), and a signal generation device 1216 (e.g., a speaker).

The secondary memory 1218 may include a machine-accessible storage medium (or more specifically a computer-readable storage medium) 1232 on which is stored one or more sets of instructions (e.g., software 1222) embodying any one or more of the methodologies or functions described herein. The software 1222 may also reside, completely or at least partially, within the main memory 1204 and/or within the processor 1202 during execution thereof by the computer system 1200, the main memory 1204 and the processor 1202 also constituting machine-readable storage media. The software 1222 may further be transmitted or received over a network 1220 via the network interface device 1208.

While the machine-accessible storage medium 1232 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

Embodiments of plasma excitation methods, apparatuses and processes based on or using a circular vertical plasma source have been disclosed.

What is claimed is:

1. A plasma source, comprising:
a ground electrode comprising a plurality of ground electrode portions; and
a power electrode comprising a plurality of power electrode portions, wherein ones of the power electrode portions are interleaved with ones of the ground electrode portions.

2. The plasma source of claim 1, wherein the plurality of ground electrode portions and the plurality of power electrode portions are bare electrode portions.

3. The plasma source of claim 1, wherein the plurality of ground electrode portions and the plurality of power electrode portions are cladded electrode portions.

4. The plasma source of claim 1, wherein the plurality of ground electrode portions comprises a plurality of concentric circular-shaped portions.

5. The plasma source of claim 1, wherein the plurality of power electrode portions comprises a plurality of concentric circular-shaped portions.

6. The plasma source of claim 1, wherein the plurality of ground electrode portions comprises a first plurality of concentric circular-shaped portions, and the plurality of power electrode portions comprises a plurality of concentric circular-shaped portions.

7. The plasma source of claim 1, wherein the plurality of ground electrode portions are electrically coupled together, and the plurality of power electrode portions are electrically coupled together.

8. The plasma source of claim 1, wherein the plasma source is for operating at a temperature in the range of 400-500 degrees Celsius.

9. A plasma process chamber, comprising:
a pedestal for supporting a workpiece in a processing volume;
a plasma source in a portion of the processing volume above the pedestal, the plasma source comprising a ground electrode comprising a plurality of ground electrode portions, and a power electrode comprising a plurality of power electrode portions, wherein ones of the power electrode portions are interleaved with ones of the ground electrode portions; and
a chamber top or lid over the plasma source.

10. The plasma process chamber of claim 9, wherein the plasma process chamber is for operating with the processing volume at a temperature in the range of 400-500 degrees Celsius.

11. The plasma process chamber of claim 9, wherein the pedestal is coupled to ground or RF.

12. The plasma process chamber of claim 9, wherein the plurality of ground electrode portions and the plurality of power electrode portions are bare electrode portions.

13. The plasma process chamber of claim 9, wherein the plurality of ground electrode portions and the plurality of power electrode portions are cladded electrode portions.

14. The plasma process chamber of claim 9, wherein the plurality of ground electrode portions comprises a plurality of concentric circular-shaped portions.

15. The plasma process chamber of claim 9, wherein the plurality of power electrode portions comprises a plurality of concentric circular-shaped portions.

16. The plasma process chamber of claim 9, wherein the plurality of ground electrode portions comprises a first plurality of concentric circular-shaped portions, and the plurality of power electrode portions comprises a plurality of concentric circular-shaped portions.

17. The plasma process chamber of claim 9, wherein the plurality of ground electrode portions are electrically coupled together, and the plurality of power electrode portions are electrically coupled together.

18. The plasma process chamber of claim 9, wherein the plasma source is for operating at a temperature in the range of 400-500 degrees Celsius.

19. A method of generating a plasma, comprising:
powering a plasma source, the plasma source comprising a ground electrode comprising a plurality of ground electrode portions, and a power electrode comprising a plurality of power electrode portions, wherein ones of the power electrode portions are interleaved with ones of the ground electrode portions.

20. The method of claim 1, wherein the plasma has a temperature in the range of 400-500 degrees Celsius.
